(19) United States
(12) Patent Application Publication
(10) Pub. No.: US 2009/0212394 A1
(43) Pub. Date: Aug. 27, 2009

(54) BIPOLAR TRANSISTOR AND METHOD OF FABRICATING THE SAME

(75) Inventors: Joost Melai, Enschede (NL); Vijayarachavan Madakasira, Louvain (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 11/912,606

(22) PCT Filed: Apr. 21, 2006
(86) PCT No.: PCT/IB06/51248

§ 371 Date: Oct. 7, 2008

(30) Foreign Application Priority Data
Apr. 28, 2005 (EP) 05103490.8
Apr. 21, 2006 (IB) PCT/IB2006/051248

(51) Int. Cl. H01L 29/73; H01L 21/331

(52) U.S. Cl. 257/587; 438/353; 257/E29.174; 257/E21.37

(57) ABSTRACT

The invention provides a bipolar transistor with an improved performance because of a reduced collector series resistance and a reduced collector to substrate capacitance. The bipolar transistor includes a protrusion (5) which size may be reduced to a dimension that cannot be achieved with lithographic techniques. The protrusion (5) comprises a collector region (21) and a base region (22), in which the collector region (21) covers and electrically connects to a first portion of a first collector connecting region (3). A second collector connecting region (13) covers a second portion of the first collector connecting region (3) and is separated from the protrusion (5) by an insulation layer (10, 11), which covers the sidewalls of the protrusion (5). A contact to the base region (22) is provided by a base connecting region (15), which adjoins the protrusion (5) and which is separated from the second collector connecting region (13) by an insulation layer (14). A collector contact (31) and a base contact (32) are formed simultaneously on an exposed portion of the second collector connecting region (13) and on a portion of the base connecting region (15) that has not been removed.

The invention relates to a bipolar transistor and a method of fabricating the same.

U.S. Pat. No. 5,001,533 discloses a method of fabricating a bipolar transistor, which comprises a collector region, a base region and an emitter region. The base region of the bipolar transistor makes an electrical contact to the collector region and to a base connecting region, which is needed to make a base contact, and the emitter region makes an electrical contact to the base region. The collector region is a drift region for majority carriers required for the bipolar action, and a electrical contact to the collector region is provided by a collector connecting region comprising a collector contact region, an epitaxially grown collector region and a polysilicon collector contact layer. The collector connecting region has a negative impact on the bipolar transistor performance, such as the frequency response, because it introduces, amongst others, a collector to substrate capacitance and a collector series resistance, which both are additional to the collector to substrate capacitance and collector series resistance of the collector region.

It is an object of the invention to provide a bipolar transistor and a method for fabricating the same in which the impact of the contact to the collector region on the performance of the bipolar transistor is reduced. According to the invention, this object is achieved by providing a bipolar transistor as claimed in claim 1.

Both the collector to substrate capacitance and collector series resistance depend on the size of the collector connecting region. Reducing the size of the collector connecting region may reduce the negative impact of the collector connecting region on the bipolar transistor performance. However, reducing the size of the collector connecting region also reduces the area available for making an electrical contact to the collector connecting region, and this area cannot be reduced below a value, which is determined by lithographic limitations such as alignment tolerances. Hence the lithographic limitations prevent a further reduction of the parasitic capacitance and resistance of the collector connecting region.

The alignment of the base connecting region to the emitter region becomes problematic when the lateral and vertical dimensions of the bipolar transistor are reduced to dimensions near or below the lithographic capability limits. A solution for this problem may be to fabricate the base region with a selective epitaxial growth step, however this fabrication method is difficult to control.

Integration of the bipolar transistor in a CMOS fabrication process is advantageous for many applications. For these BiCMOS fabrication processes often the collector region is fabricated before the CMOS field oxide or shallow trench insulation (STI) formation, adding long and expensive fabrication steps to the standard CMOS process such as an implant with a high doping level, a long furnace anneal and a long epitaxial growth step. These additional fabrication steps also inadvantageously influence the subsequent fabrication steps that are needed for the fabrication of CMOS devices.

An additional advantage of the invention is that also these problems are solved by a bipolar transistor and a method of making the same according to the invention.

A bipolar transistor according to the invention comprises a protrusion, which comprises a base region of a second semiconductor type on a collector region of a first semiconductor type, thereby forming a base-collector junction. The collector region covers and electrically connects to a first portion of a first collector connecting region of the first semiconductor type. A contact to the collector region may be provided by contacting a second portion of the first collector connecting region, which is not covered by the protrusion, with a second collector connecting region, which is separated from the protrusion by a first insulating layer. Hence the second collector connecting region is electrically connected to the collector region via the first collector connecting region. The distance between the second collector connecting region and the collector region determines, amongst others, the size of the total collector connecting region, comprising the first and the second collector connecting region. This distance is determined by the thickness of the first insulation layer, and is therefore independent of photolithographic techniques. Hence the size of the total collector connecting region is smaller than can be achieved in the prior art, because in the prior art this size is determined by the capability of photolithographic techniques. The reduced size of the total collector connecting region decreases the collector series resistance and the collector to substrate capacitance, which reduces the negative impact of the total collector connecting region on the performance of the bipolar transistor.

Further, a second insulation layer covers the second collector connecting region and a base connecting region of the second semiconductor type covers the second insulation layer, the base connecting region adjoining and electrically connecting the base region. The size of the base connecting region is reduced, because it is self-aligned with respect to the base region and because it directly electrically connects the base region, and therefore the negative influence of the base connecting region on the bipolar transistor performance is reduced.

Further, the bipolar transistor comprises an emitter region, which covers a portion of the base region, thereby forming an intrinsic base-emitter junction.

In an embodiment, the bipolar transistor comprises a collector contact on an exposed portion of the second collector connecting region, and a base contact on a portion of the base connecting region, which is an unexposed portion of the second collector connecting region. The advantage of this method of contacting the collector and base region is that the collector and base contact area is reduced, thereby reducing the total device area.

A method of fabricating the bipolar transistor according the invention provides a protrusion on a first portion of a first collector connecting region of a first semiconductor type, the first collector connecting region being provided in a semiconductor substrate. The protrusion comprises a collector region, a base region on the collector region and sidewalls covered with a first insulating layer. A second collector connecting region is formed on a second portion of the first collector region and adjoins the first insulation layer. On the second collector connecting region a second insulation layer is formed and a portion of the first insulation layer is removed, thereby exposing a portion of the base region. Then a base connecting region of the second semiconductor type is formed on the second insulation layer, the base connecting region adjoining and electrically connecting to the base region. Thereafter an emitter region is formed on a portion of the base region.

The method according to the invention provides both the base region, the base connecting region, the collector region and the first and the second collector connecting regions self-aligned to the emitter region independent of lithographic techniques. The second collector connecting region is formed self-aligned with respect to the collector region with a mutual distance, which is determined by the thickness of the first insulation layer and which is therefore independent of photolithographic techniques. This method decreases the impact of parasitic parameters, such as the collector to substrate capacitance, on the performance of the bipolar transistor because of a reduction of the collector to substrate area and the collector series resistance, which is achieved by a smaller collector connecting region. Further, this method provides an easier integration of the bipolar transistor in a CMOS process, because the collector region and the first and second collector connecting regions are fabricated after the field oxide or STI formation, thereby avoiding a long furnace anneal step and reducing the interaction between the field oxide or STI formation and the fabrication steps of the bipolar transistor. Another advantage of applying this method in a BiCMOS process is that the collector and base region may be fabricated in one epitaxial step instead of at least two separate epitaxial steps thereby reducing the fabrication costs further. Further, the masking step to form an electrical connection to the collector region is eliminated, because the connection to the collector region is completely self-aligned. Another advantage is that the dopant level of the first collector connecting region may be smaller because it is closer to the collector region. The lower dopant level results in less damage to the semiconductor substrate, thereby reducing the required furnace, anneal time and/or temperature.

In an embodiment a collector contact and a base contact are simultaneously formed by removing a portion of the second base layer and a portion of the second insulation layer, thereby exposing a portion of the second collector connecting region. The collector contact is formed on the exposed portion of the second collector connecting region, and the base contact is formed on a portion of the base connecting region, which has not been removed. The advantage of this method of contacting the collector and base region is that the collector and base contact area is reduced, thereby reducing the total device area.

In an embodiment, a fabrication step is applied that reduces the size of the protrusion to a value that may be smaller than can be obtained with photolithographic techniques. This method reduces the active region of the bipolar transistor, which comprises the base-collector junction and the base-emitter junction, and hence reduces the device area and the influence of parasitic parameters such as base-collector capacitance. This fabrication step may comprise an oxidation and an etching step.

These and other aspects of the invention will be further elucidated and described with reference to the drawings, in which:

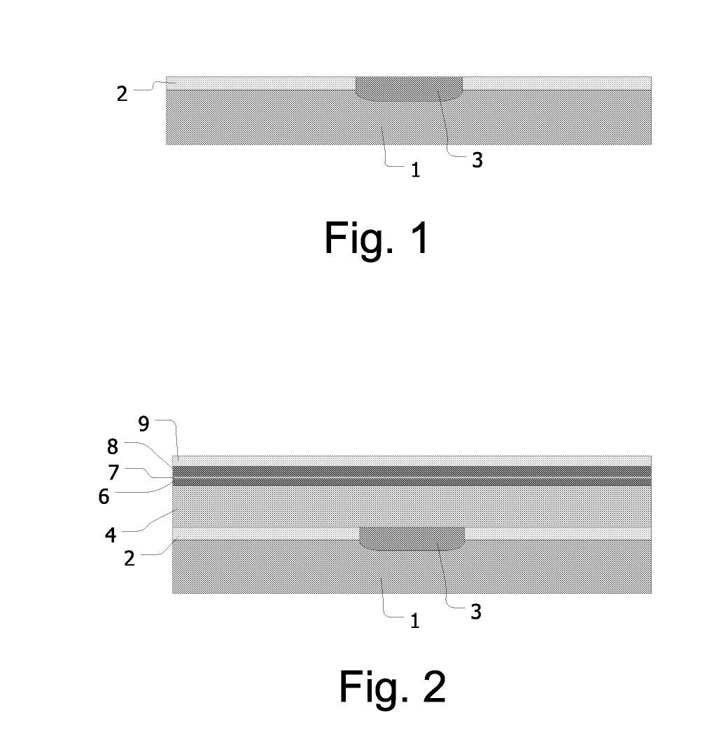

FIGS. 1-10 and 12 illustrate cross-sectional views of various stages of the fabrication of a bipolar transistor according to an embodiment of the invention;

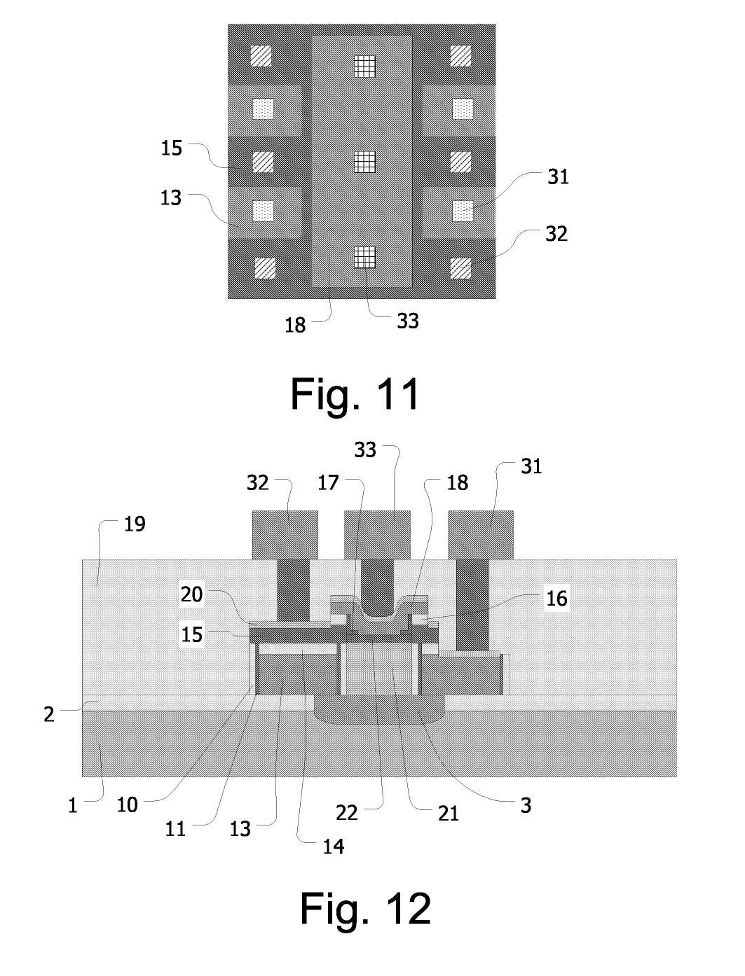

FIG. 11 illustrates a schematic top view of a bipolar transistor according to an embodiment of the invention.

The Figures are not drawn to scale. In general, identical components are denoted by the same reference numerals in the Figures.

FIG. 1 illustrates an initial structure comprising a standard p-doped silicon substrate 1 with a shallow trench insulation region 2 and a first collector connecting region 3, which is fabricated using photolithography and implantation of n-type dopants. Typically As ions are implanted to create the first collector connecting region 3. Beneath the insulation region 2 optionally a p-type region may be implanted that improves the insulation between the n-type collector connecting regions 3. Alternatively, the substrate 1 may comprise n-type semiconductor material.

Thereafter a non-selective epitaxial growth forms a stack of layers, as is illustrated in FIG. 2. This stack of layers comprises an n-type silicon layer 4 and a SiGe layer 6 comprising a silicon emitter cap layer. The SiGe layer 6 may also comprise a relatively thin boron doped layer and a small amount of carbon to limit the boron diffusion, for example 0.2 at %. Forming the stack of layers in one fabrication step is advantageous because it reduces the number of fabrications steps, for example fabrication steps that clean the interface between the layers are not needed. Furthermore, the use of epitaxial growth enables a very precise control of the doping profile in the layers. Thereafter, a silicon nitride layer 8 and a silicon dioxide layer 9, for example undensified TEOS (Tetraethyl Orthosilicate) are formed on the silicon dioxide layer 7.

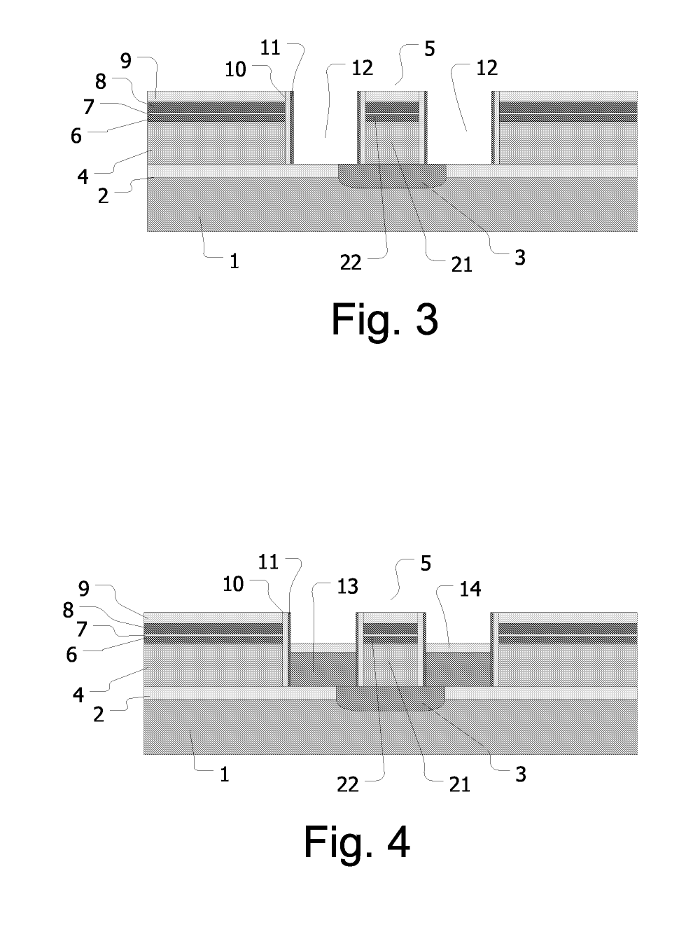

Photolithography is applied to create a window in which the stack of layers is etched thereby forming a protrusion 5 and a trench 12 surrounding and adjoining the protrusion 5, as is illustrated in FIG. 3. The protrusion 5 comprises a collector region 21, a base region 22, a portion of the silicon dioxide layer 7, a portion of the silicon nitride layer 8 and a portion of the silicon dioxide layer 9. The collector region 21 comprises a portion of the n-type silicon layer 4 and the base region 22 comprises a portion of the SiGe layer 6. The trench 12 covers at least portion of the first collector connecting region 3, and, although not required, in this embodiment also a portion of the insulation region 2. Hence the protrusion 5 is located on the first collector connecting region 3, thereby forming an electrical connection between the collector region 21 and the first collector connecting region 3. Applying an isotropic etching process may reduce the size of the protrusion 5, but also other methods, such as oxidation followed by an oxide etch of the protrusion 5, may be applied to reduce the size of the protrusion 5 to a value that may be smaller than can be obtained with photolithographic techniques. Next the sidewalls of the trench 12 are covered with spacers comprising a silicon dioxide layer 10, for example undensified TEOS (Tetraethyl Orthosilicate), and a silicon nitride layer 11.

Thereafter an in-situ doped n-type polysilicon layer is deposited covering all exposed surfaces and filling the trench 12. Chemical mechanical polishing may be applied to planarize the polysilicon layer, after which an etch back fabrication step is used to remove the polysilicon layer which is above the level of the collector region 21, thereby creating a second collector connecting region 13, which comprises the n-type polysilicon layer, as is illustrated in FIG. 4. In this way an electrical connection is formed between the second collector connecting region 13 and the first collector connecting region 3. Thereafter a silicon dioxide layer 14 is formed on the second collector connecting region 13 with a low temperature thermal oxidation, leaving a portion of the silicon nitride layer 11 exposed.

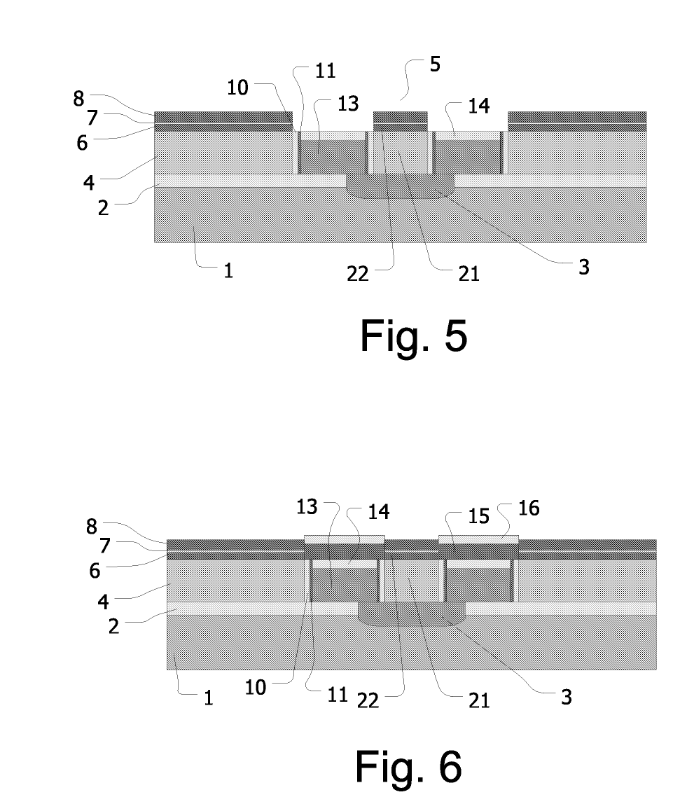

Thereafter the exposed portion of the silicon nitride layer 11 is removed with a selective etching step, thereby exposing a portion of the silicon dioxide layer 10. For example a phosphoric acid solution may be applied to etch the exposed portion of the silicon nitride layer 11 selectively in relation the silicon dioxide layers 9 and 10. Subsequently the exposed portion of the silicon dioxide layer 10 and the silicon dioxide layer 9 are removed, thereby exposing sidewalls of the base region 22, while not affecting the silicon dioxide layer 14, as is illustrated in FIG. 5. The silicon dioxide layer 14 is not removed, because it isolates the second collector connecting region 13 from other, to be fabricated, semiconductor layers. For example HF (hydrofluoric acid) may be applied to etch the silicon dioxide layers 9 and 10 while simultaneously hardly affecting the silicon dioxide layer 14, because the silicon dioxide layer 14 is formed with a thermal oxidation, and the silicon dioxide layers 9 and 10 comprise for example undensified TEOS (Tetraethyl Orthosilicate), which etches faster than thermal oxide.

Subsequently, a p-type in-situ doped polysilicon layer is deposited covering all exposed surfaces. Chemical mechanical polishing may be applied to planarize the polysilicon layer, after which an etch back fabrication step is used to remove the polysilicon layer which is above the level of the top surface of the base region 22, thereby creating a base connecting region 15, as is illustrated in FIG. 6. The base connecting region 15 adjoins and electrically connects to the base region 22. A silicon dioxide layer 16 is formed on the base connecting region 15 with a low temperature thermal oxidation.

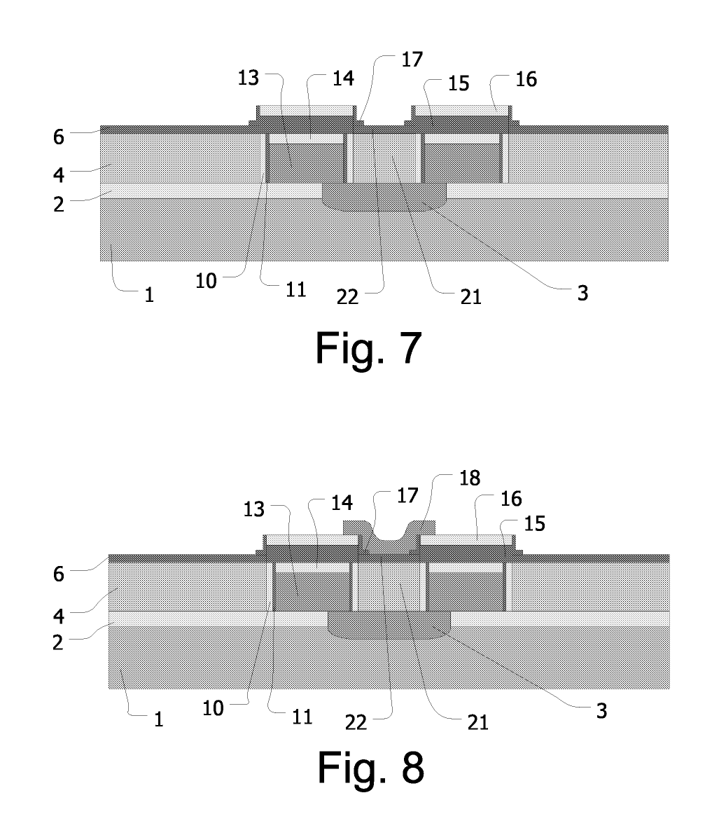

Thereafter the silicon nitride layer 8 is removed with a selective wet etching process, followed by the removal of the silicon dioxide layer 7, thereby forming exposed sidewalls comprising the silicon dioxide layer 16 and a portion of the base connecting region 15, as is illustrated in FIG. 7. The silicon dioxide layer 7, which is a TEOS (Tetraethyl Orthosilicate) layer, is etched selectively with respect to the silicon dioxide layer 16, which is a thermally grown silicon dioxide. Inside spacers 17 are formed by using standard deposition and etching techniques. The spacers 17 preferably have an L-shape, but also other shapes, such as a D-shape, are possible. The spacers 17 cover the exposed sidewalls and may comprise for example silicon nitride. A portion of the base region 22 which is not covered with the spacers 17 defines a region where the emitter to base junction will be fabricated.

Thereafter, as is illustrated in FIG. 8, an emitter region 18 is formed by depositing and patterning an in-situ doped n-type polysilicon layer. Alternatively, the emitter region 18 may be formed by applying differential epitaxial growth which forms a monosilicon layer on the base region 22 and a polysilicon layer on all other regions, followed by patterning of this polysilicon layer.

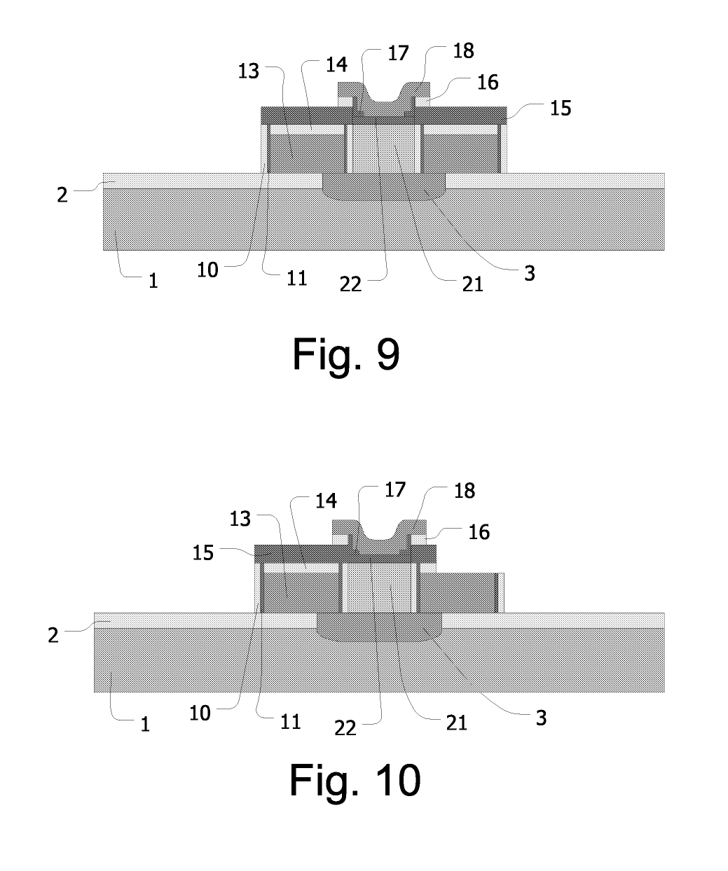

Subsequently, as is illustrated in FIG. 9, the exposed spacers 17, the exposed portion of the silicon dioxide layer 16, the SiGe layer 6 and the silicon layer 4 are removed by standard etching techniques, thereby exposing the base connecting region 15.

Thereafter a collector-base contact window is defined by applying a photolithographic mask. Subsequently, as is illustrated in FIG. 10, a portion of the second collector connecting region 13 is exposed by removing a portion of the base connecting region 15 and a portion of the silicon dioxide layer 14 with standard etching techniques, which portions are exposed by the collector-base contact window. The photolithographic mask also defines a portion of the base connecting region 15, which is not removed and remains exposed. Hence, with one photolithographic mask, an exposed portion of the second collector connecting region 13 and an exposed portion of the base connecting region 15 are defined simultaneously. The ratio of the area of the exposed portion of the second collector connecting region 13 and the area of the exposed portion of the base connecting region 15 may be adapted to set the collector and base series resistances depending on the requirements of the application of the bipolar transistor.

FIG. 11, which is a schematic top view of the fabricated device, illustrates an embodiment of the use of the photolithographic mask, defining an exposed portion of the second collector connecting region 13 and an exposed portion of the base connecting region 15. Subsequently the exposed portion of the second collector connecting region 13, the exposed portion of the base connecting region 15 and the emitter region 18 may be silicided, thereby creating a metal silicide layer 20 covering these regions and reducing the parasitic series resistance.

Next, as is illustrated in FIG. 11 and FIG. 12, a collector contact 31, a base contact 32 and an emitter contact 33 are formed respectively on the exposed portion of the second collector connecting region 13, on the exposed portion of the base connecting region 15 and on the emitter region 18.

In summary, the invention provides a bipolar transistor with an improved performance because of a reduced collector series resistance and a reduced collector to substrate capacitance. The bipolar transistor includes a protrusion which size may be reduced to a dimension that cannot be achieved with lithographic techniques. The protrusion comprises a collector region and a base region, in which the collector region covers and electrically connects to a first portion of a first collector connecting region. A second collector connecting region covers a second portion of the first collector connecting region and is separated from the protrusion by an insulation layer, which covers the sidewalls of the protrusion. A contact to the base region is provided by a base connecting region, which adjoins the protrusion and which is separated from the second collector connecting region by an insulation layer. A collector contact and a base contact are formed simultaneously on an exposed portion of the second collector connecting region and on a portion of the base connecting region that has not been removed.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. A bipolar transistor comprising: a semiconductor substrate with a first collector connecting region of a first semiconductor type, a protrusion having sidewalls covered with a first insulation layer and comprising a collector region of the first semiconductor type and a base region of a second semiconductor type covering and electrically connecting to the collector region, which covers and electrically connects to a first portion of the first collector connecting region, a second collector connecting region of the first semiconductor type adjoining the first insulation layer and covering a second portion of the first collector connecting region, a second insulation layer covering the second collector connecting region, and a base connecting region of the second semiconductor type on the second insulating layer, said base connecting region adjoining and electrically connecting to the base region.

2. A bipolar transistor according to claim 1, further comprising a collector contact on an exposed portion of the second collector connecting region, and a base contact on a portion of the base connecting region where the second collector connecting region is not exposed.

3. A bipolar transistor according to claim 1, in which the base region comprises a p-type epitaxial silicon germanium and a p-type silicon layer.

4. A bipolar transistor according to claim 1, in which the semiconductor substrate comprises an n-type silicon material.

5. A method for fabricating a bipolar transistor, the method comprising:
providing a semiconductor substrate with a first collector connecting region of a first semiconductor type, forming a protrusion having sidewalls covered with a first insulation layer and comprising a collector region of the first semiconductor type and a base region of a second semiconductor type covering and electrically connecting to the collector region, which covers and electrically connects to a first portion of the first collector connecting region,
forming a second collector connecting region of the first semiconductor type adjoining the first insulation layer and covering a second portion of the first collector connecting region,
forming a second insulation layer on the second collector connecting region,
removing a portion of the first insulation layer from the sidewalls of the protrusion thereby exposing a portion of the base region, and
forming a base connecting region of the second semiconductor type on the second insulating layer, the base connecting region adjoining and electrically connecting to the base region.

6. The method as claimed in claim 5, further comprising: moving a portion of the base connecting region and a portion of the second insulation layer, thereby exposing a portion of the second collector connecting region, and forming a collector contact on the exposed portion of the second collector connecting region, and a base contact on the base connecting region.

7. The method as claimed in claim 5, in which the bipolar transistor is integrated in a CMOS process after fabrication of field oxide or shallow trench insulation.

8. The method as claimed in claim 5, in which the protrusion is formed with an epitaxial growth followed by a lithography step.

9. The method as claimed in claim 5, in which a fabrication step is applied to reduce the size of the protrusion.

10. The method as claimed in claim 9, in which the fabrication step to reduce the size of the protrusion comprises an oxidation followed by an oxide etch.
